(19) United States
(12) Patent Application Publication
(10) Pub. No.: US 2020/0307036 A1
(43) Pub. Date: Oct. 1, 2020

(54) FORMING APPARATUS AND METHOD FOR MANUFACTURING ARTICLE BY USING FORMING APPARATUS

(71) Applicant: CANON KABUSHIKI KAISHA, Tokyo (JP)

(72) Inventor: Satoshi Iwatani, Utsunomiya-shi (JP)

(21) Appl. No.: 16/829,302

(22) Filed: Mar. 25, 2020

(30) Foreign Application Priority Data
Mar. 29, 2019 (JP) 2019-068855

(51) Int. Cl. B29C 35/08; B29C 43/02; H01L 21/027; H01L 21/308

(52) U.S. Cl. CPC B29C 35/0805; B29C 43/021; B29C 2035/0827; H01L 21/3086; H01L 21/0274

(57) ABSTRACT

A forming apparatus includes a substrate holder that holds a substrate; a support table that supports the substrate holder; a mold holder that holds a mold; a driving unit that brings a photo-curable formable material applied to the substrate and the mold into contact with each other; an irradiation unit that irradiates the formable material with light while the formable material and the mold are maintained in contact with each other by the driving unit, the irradiation unit including a light-emitting-element array including light emitting elements arranged on the support table or the substrate holder; and an optical member that is positioned further in a direction from the support table to the mold holder than a position of the mold holder, the optical member guiding light from the light emitting elements toward the formable material on the substrate.

### BACKGROUND OF THE INVENTION

### Field of the Invention

The present disclosure relates to a forming apparatus that forms a photo-curable formable material into a desired shape by using a mold. The present disclosure also relates to a method for manufacturing an article by using the forming apparatus.

### Description of the Related Art

Forming apparatuses that form a photo-curable formable material into a desired shape by using a mold have been known. Such a forming apparatus is used in, for example, a process of manufacturing a semiconductor device or a microstructure.

PCT Japanese Translation Patent Publication No. 2011-529626 discloses a forming apparatus for forming a flat layer on a substrate by using a mold having a flat surface. PCT Japanese Translation Patent Publication No. 2012-505544 discloses a forming apparatus for forming a pattern layer on a substrate by using a mold having a pattern including projections and recesses. The forming apparatus disclosed in PCT Japanese Translation Patent Publication No. 2012-505544 is referred to also as an imprint apparatus.

PCT Japanese Translation Patent Publication No. 2011-529626 discloses a process of solidifying a formable material by using broad-band ultraviolet radiation generated by an energy source. However, the energy source is not described in detail.

Although ultraviolet (UV) lamps are typically used to generate high-intensity ultraviolet radiation, according to PCT Japanese Translation Patent Publication No. 2012-505544, light emitting devices (LEDs) are used to generate ultraviolet radiation.

The UV lamps are advantageous in that high-intensity ultraviolet rays can be easily obtained, but are disadvantageous in that they generate a large amount of heat and that a radiation system thereof has a large and complex structure. The LEDs generate ultraviolet rays with an intensity lower than that of ultraviolet rays generated by the UV lamp, and therefore a device for reducing the optical path distance is required.

According to PCT Japanese Translation Patent Publication No. 2012-505544, the LEDs are arranged obliquely above a mold holder, and the therefore the optical path distance cannot be easily reduced. In addition, although a structure in which optical fibers are provided to guide light to a housing of the mold holder is described, the optical fibers cause a large optical loss. Therefore, this structure is disadvantageous in terms of the amount of radiation and efficiency.

### SUMMARY OF THE INVENTION

A forming apparatus according to the present disclosure includes a substrate holder that holds a substrate; a support table that supports the substrate holder; a mold holder that holds a mold; a driving unit that brings a formable material and the mold into contact with each other, the formable material being photo-curable and applied to the substrate held by the substrate holder, the mold being held by the mold holder; an irradiation unit that irradiates the formable material with light for curing the formable material while the formable material and the mold are maintained in contact with each other by the driving unit, the irradiation unit including a light-emitting-element array including a plurality of light emitting elements arranged on the support table or the substrate holder; and an optical member that is positioned further in a direction from the support table to the mold holder than a position of the mold holder, the optical member guiding light from the plurality of light emitting elements toward the formable material on the substrate.

Further features of the present disclosure will become apparent from the following description of exemplary embodiments with reference to the attached drawings.

### BRIEF DESCRIPTION OF THE DRAWINGS

FIG. 1 illustrates a forming processor of a forming apparatus.

FIG. 2 illustrates an optical member of the forming processor.

FIG. 3 illustrates another optical member of the forming processor.

FIGS. 4A to 4C illustrate regions of the optical members.

FIGS. 5A to 5C illustrates a forming operation performed by the forming apparatus.

FIG. 6 illustrates a forming processor according to a first modification.

FIG. 7 illustrates a forming processor according to a second modification.

FIG. 8 illustrates a forming processor according to a third modification.

### DESCRIPTION OF THE EMBODIMENTS

### First Embodiment

Embodiments of the present disclosure will now be described with reference to the drawings.

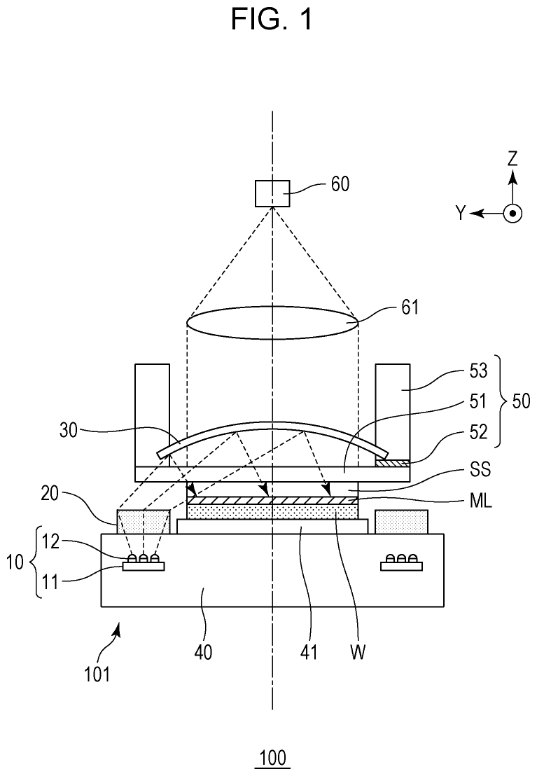

FIG. 1 illustrates an example of a forming processor of a forming apparatus. The forming apparatus forms a photo-curable formable material into a desired shape. Although an apparatus that cures a material by irradiation with ultraviolet rays will be described as an example, the forming apparatus is not limited to this. In addition, although a wafer used in a semiconductor manufacturing process will be described as an example of a substrate, the substrate is not limited to this. A typical wafer has a circular outer periphery with a diameter of 300 mm or 200 mm Although a mold SS having a circular outer periphery of the same size as that of the wafer will be described as an example, the mold SS is not limited to this.

FIG. 1 illustrates a forming apparatus 100 including a forming processor 101. The forming processor 101 includes an irradiation unit 10 that emits light for curing a formable material ML applied to a substrate W. The irradiation unit 10 includes a light-emitting-element array 11 including a plurality of light emitting elements and a microlens array 12 including a plurality of microlenses that converge light emitted from the light emitting elements of the light-emitting-element array 11. The forming processor 101 also includes optical members 20 and 30 that guide the light from the microlens array 12 to the formable material ML. A stage (support table) 40 supports a chuck (substrate holder) 41 that holds the substrate W. A head 50 includes a chuck 51 (mold holder) that holds the mold SS, a driving unit 52 that drives the chuck 51, and a support unit 53 that supports the driving unit 52. The mold SS is brought into contact with the formable material ML applied to the substrate W. In this state, the formable material ML is irradiated with the light from the irradiation unit 10, so that the formable material ML is cured. The mold SS has a flat surface. When the mold SS is moved upward after the formable material ML is cured, the cured formable material ML has a surface corresponding to the surface of the mold SS. Thus, the formable material is formed into a desired shape.

The stage 40 is capable of moving along a base while the substrate W is held by the chuck 41. When the substrate W is placed onto or removed from the chuck 41, the stage 40 is moved to a position separated from a position below the head 50 so that interference (physical contact) between a conveyance arm and the head 50 can be easily prevented. The relative position between the mold SS and the substrate W can be finely adjusted by moving the stage 40 by small distances before the formable material ML on the substrate W and the mold SS are brought into contact with each other. A well-known mechanism may be used as a mechanism for driving the stage. The stage 40 may include a top plate and a plate-shaped member connected to the top plate.

The chuck 41 is fixed to the stage 40 by being fastened or attracted to the stage 40. The chuck 41 has a holding surface that holds the substrate W. The chuck 41 may hold the substrate W by a well-known method, such as a vacuum chucking method or an electrostatic chucking method. When the vacuum chucking method is used, the substrate W can be held by connecting grooves formed in the surface of the chuck 41 to a negative-pressure-generating device and setting the pressure in the grooves to a negative pressure while the substrate W is placed on the holding surface. The chuck 41 may have holes for enabling pins to project from the holding surface when the substrate W is placed onto or removed from the holding surface. When the pins are moved to project from the holding surface by using a mechanism for moving the pins vertically, the substrate W can be picked up and released by the conveyance arm while the substrate W is separated from the holding surface and supported by the pins. The stage 40 may also be used when the mold SS is picked up and released by the conveyance arm. The stage 40 and the chuck 41 may each be made of a well-known material. The material may be, for example, a ceramic, a metal, an alloy, or glass.

The head 50 will now be described. The chuck 51 has a holding surface that holds the mold SS. The chuck 51 may hold the mold SS by a well-known method, such as a vacuum chucking method or an electrostatic chucking method. When the vacuum chucking method is used, the mold SS can be held by connecting grooves formed in the surface of the chuck 51 to a negative-pressure-generating device and setting the pressure in the grooves to a negative pressure while the mold SS is placed on the holding surface.

The chuck 51 has a circular outer periphery with a diameter greater than the diameter of the mold SS. The chuck 51 is structured such that the formable material ML can be irradiated with light from above the chuck 51 when the mold SS is held by the chuck 51. Therefore, at least a portion of the chuck 51 may be made of a material having an ultraviolet transmittance of greater than or equal to 60%. More preferably, the ultraviolet transmittance of the material may be greater than or equal to 70% or greater than or equal to 80%. According to the present embodiment, not only a portion of the chuck 51 that comes into contact with the mold SS but also a portion of the chuck 51 that does not come in contact with the mold SS is made of a material having a high ultraviolet transmittance. Instead of using a material having a high transmittance, the chuck 51 may have a recess (space) that does not block light.

The driving unit 52 is supported by the support unit 53. The driving unit 52 drives the chuck 51 to change the position of the chuck 51 relative to the support unit 53 in the vertical direction (Z direction). The driving unit 52 may be, for example, an actuator such as a piezoelectric actuator or a voice coil motor. A pneumatic actuator may also be used depending on the required specifications (for example, responsiveness). A plurality of actuators may be provided so that the chuck 51 may be driven in tilting directions (θx and θy directions). When the chuck 51 is driven in the tilting directions, the relative inclination between the mold SS and the substrate W can be adjusted when the mold SS and the formable material ML are brought into contact with each other. The driving unit 52 may be capable of moving the chuck 51 in the X and Y directions. In such a case, for example, the relative position between the mold SS and the substrate W can be finely adjusted by moving the chuck 51 by small distances in the X and Y directions before the formable material ML on the substrate W and the mold SS are brought into contact with each other.

The support unit 53 is fixed to a support structure (not shown) by, for example, being fastened to the support structure. The driving unit 52 and the support unit 53 may be disposed in a housing. In such a case, the driving unit 52 and the support unit 53 may be fixed to the support structure by the housing. Alternatively, the support unit 53 may serve as a housing.

The head 50 may include a mechanism for bending the mold SS held by the chuck 51 toward the substrate W. For example, the chuck 51 may have a recess, and the mold SS may be bent by connecting a local space surrounded by the mold SS that is held and the recess to a pressure control device and setting the pressure in the local space to a positive pressure.

The forming processor 101 includes an observation unit 60 for observing the formable material ML that is in contact with the mold SS. The observation unit 60 includes a light source that emits observation light and an imaging device (imaging unit). The wavelength of the light source may be different from the wavelength of light used to cure the formable material. In the present embodiment, an LED having a wavelength range of 450 nm to 750 nm, which is a wavelength range of visible light, is used. The formable material is irradiated with the observation light from the light source from above the chuck 51 through a lens 61. In the present embodiment, the lens 61 forms a telecentric optical system. According to this structure, the states of the mold SS and the formable material ML can be observed during the forming operation. The observation unit 60 may observe the entire region in which the formable material ML is subjected to a forming process.

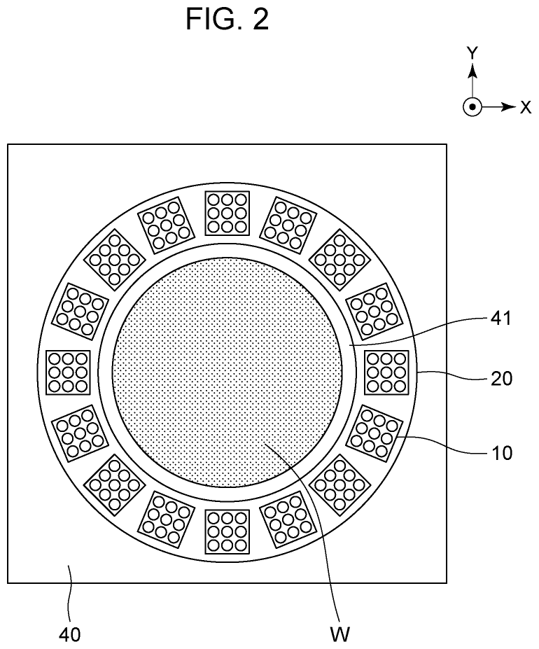

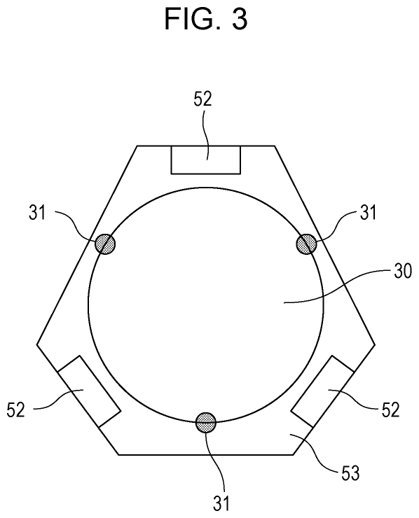

The irradiation unit 10 will now be described with reference to FIGS. 1 to 3. FIG. 2 is a top view of the stage 40. FIG. 3 is a top view of the optical member 30.

The irradiation unit 10 includes the light emitting elements that are two-dimensionally arranged along an XY plane, and is placed on the stage 40. In the present embodiment, the irradiation unit 10 includes the light-emitting-element array 11 including a plurality of LED modules arranged along the outer periphery of the chuck 41. Each LED module includes a rectangular electrical printed circuit board and a plurality of LEDs (light emitting elements) that are two-dimensionally arranged on the electrical printed circuit board. The irradiation unit 10 is disposed in a recess formed in the stage 40, and the microlens array 12 is disposed above the light-emitting-element array 11. The microlens array 12 includes a plurality of microlenses. The microlens array 12 converges diverging light emitted from each LED, and guides the light toward the optical member 20 disposed above the microlens array 12.

The optical member 20 guides the light emitted from the light-emitting-element array 11 and transmitted through the microlens array 12 toward the optical member 30. The optical member 30 changes the direction of the light so that the light emitted upward from the light-emitting-element array 11 travels toward the center of the chuck 41. A flat plate-shaped diffractive optical element may be used as the optical member 20.

Although the optical member 20 having an annular shape is provided in the present embodiment, a plurality of optical members may be arranged such that each optical member is disposed above one of the LED modules with a space therebetween.

In the present embodiment, the light-emitting-element array 11 is disposed on either side of the chuck 41, and is disposed to surround the chuck 41. Such an arrangement is advantageous over an arrangement in which the light-emitting-element array 11 is disposed on one side of the chuck 41 in terms of intensity and uniformity of light. In addition, the arrangement in which the LEDs are symmetric about a line that passes through the center of the chuck 41 (for example, line extending in the X or Y direction in FIG. 2) is advantageous in terms of uniformity of light.

The optical member 30 is disposed above the chuck 51, and is supported by the support unit 53 or the housing (not shown) with a plurality of mounting portions 31 disposed therebetween. The optical member 30 is located further in the direction from the stage 40 and the chuck 41, which hold the substrate, toward the mold SS and the chuck 51 (+Z direction) than the mold SS and the chuck 51. The optical member 30 guides the light from the light-emitting-element array 11 toward the formable material ML that is in contact with the mold SS. The optical member 30 may be a concave mirror having a reflective surface that faces the substrate W, and may be an elliptical mirror. The optical member 30 is made of a material capable of transmitting the observation light from the observation unit 60 (visible light in the present embodiment). Thus, at least a portion of the optical member 30 may be made of a material capable of reflecting ultraviolet light and transmitting visible light. The material may have a transmittance of greater than or equal to 60% for the observation light. More preferably, the transmittance of the material for the observation light may be greater than or equal to 70%, or greater than or equal to 80%. The reflective surface of the optical member 30 may have a light scattering structure.

The mounting portions 31 are disposed at three positions along the outer periphery of the optical member 30. The mounting portions 31 may be arranged 120° apart from each other around the center of the optical member 30. An adhesive or a flexure structure may be disposed between each mounting portion 31 and the support unit 53. Also, a well-known kinematic mount may be used. By using an adhesive, a flexure structure, or a kinematic mount, deformation of the optical member 30 due to force applied by the support unit 53 can be reduced.

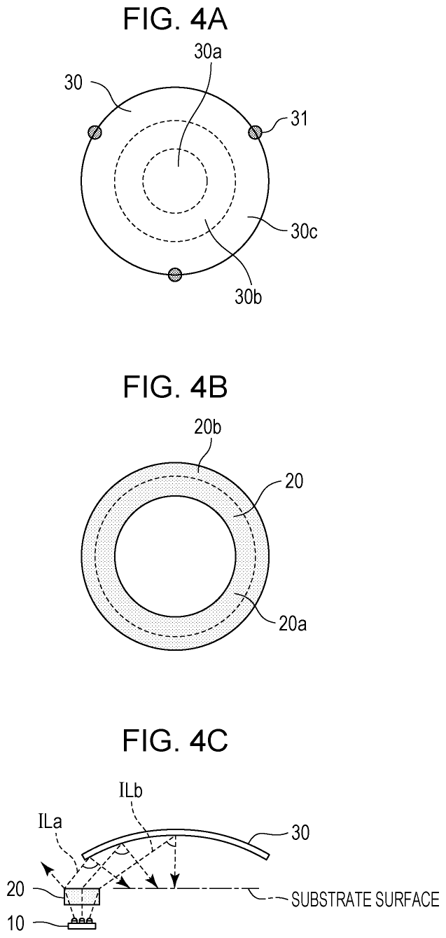

Examples of the optical member 20 and the optical member 30 will be described with reference to FIGS. 4A to 4C. FIGS. 4A to 4C illustrate the differences in optical characteristics between regions of the optical member 20 and the optical member 30. As illustrated in FIG. 4A, the optical member 30 has a central region 30a including the center of the optical member 30, an outer peripheral region 30c including the outer periphery of the optical member 30, and an intermediate region 30b located between the central region 30a and the outer peripheral region 30c.

The optical member 30 is configured such that the reflectance of the central region 30a is higher than the reflectance of the intermediate region 30b and that the reflectance of the intermediate region 30b is higher than the reflectance of the outer peripheral region 30c. A reflective film such as a dielectric multilayer film may be provided so that the regions have different reflectances. When the reflectance varies depending on the position in the radial direction (reflectance is high in the central region and low in the outer peripheral region) as described above, the illuminance is more uniform than when all of the regions have the same reflectance. The reflectance may be selected from a range of greater than or equal to 80% (and less than 100%).

Instead of forming the optical member 30 such that different regions thereof have different reflectances, the optical member 30 may be formed such that different regions thereof have different diffusion performances. In such a case, the optical member 30 is configured such that the diffusion angle of the central region 30a is less (narrower) than the diffusion angle of the intermediate region 30b, and the diffusion angle of the intermediate region 30b is less (narrower) than the diffusion angle of the outer peripheral region 30c.

As illustrated in FIG. 4B, the optical member 20 includes an inner region 20a and an outer region 20b. The optical member 20 is a diffractive optical element, and the diffraction pitch of the inner region 20a is greater (coarser) than the diffraction pitch of the outer region 20b. According to such a structure, light is more easily diffused in the outer region 20b than in the inner region 20a, so that the illuminance on the substrate W is more uniform. The optical member 20 may have diffraction gratings of different shapes instead of different diffraction pitches.

The effects of the above-described optical members 20 and 30 will be described with reference to FIG. 4C. In FIG. 4C, ILa and ILb denote light rays. As is clear from FIG. 4C, the distance by which the light ray ILb is guided from the LEDs to the substrate W is longer than the distance by which the light ray ILa is guided from the LEDs to the substrate W. Even when the light-emitting-element array 11 has a uniform light-emitting surface, the illuminance distribution is not uniform due to the differences in the distance along which the light is guided. In the present embodiment, at least one of the optical members 20 and 30 has different optical characteristics in different regions (for example, inner and outer regions of the chuck 41) so that the illuminance distribution on the substrate W irradiated with the light emitted from the light-emitting-element array 11 is uniform.

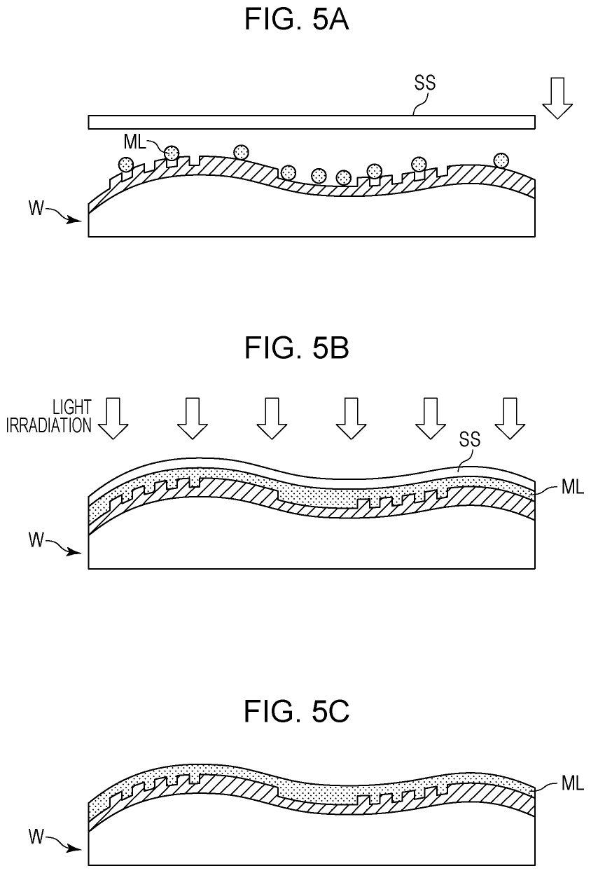

A forming operation performed by using the forming processor 101 will now be described with reference to FIGS. 5A to 5C. In the present embodiment, an apparatus that performs a forming process by using a mold having a flat surface will be described.

First, the substrate W to which the formable material ML is applied is placed on the chuck 41. Next, the substrate W held by the chuck 41 is positioned to face the mold SS held by the chuck 51. Then, the mold SS is moved downward (toward the substrate W) by the driving unit 52 (see FIG. 5A) so that the mold SS and the formable material ML come into contact with each other. After that, the irradiation unit 10 emits light so that the formable material ML is irradiated with light that has passed through the optical members 20 and 30 and the mold SS (see FIG. 5B). More specifically, the light emitted from the irradiation unit 10 is reflected by the optical member 30, which is located further in the +Z-axis direction than the mold SS, after passing through the mold SS once, and then passes through the mold SS again so that the formable material ML is irradiated with the light. The light emitted from the irradiation unit does not necessarily pass the mold SS before reaching the optical member 30.

As a result, photocuring of the formable material ML occurs and the formable material ML is cured. Finally, the mold SS is removed from the cured formable material ML by the driving unit 52 (see FIG. 5C). The formable material ML on the substrate W may be formed into a desired shape by the above-described process. The above-described forming process is performed simultaneously over the entire surface of the substrate W.

In the present embodiment, the mold SS has a thickness of greater than or equal to 0.3 mm and less than or equal to 1.0 mm, more preferably greater than or equal to 0.5 mm and less than or equal to 0.7 mm. The mold SS is made of a material capable of transmitting ultraviolet light. The material may be, for example, quartz. The mold SS does not have a pattern for a device, such as a circuit pattern, but has a flat surface. Such a mold may be referred to as a flattening member or a superstrate. The mold SS may have a pattern (mark) for positioning instead of a pattern for a device. Such a pattern (mark) is, for example, used to adjust the relative position between the mold SS and the substrate W in the forming process, and may be referred to as an alignment mark.

As is clear from FIGS. 5A to 5C, when the mold SS comes into contact with the formable material, the mold SS follows the waving shape of the substrate but forms a flat surface on projections and recesses of an underlying pattern in local regions. In this specification, the meaning of the term “flattening apparatus” includes an apparatus that flattens local regions as described above.

The flattening apparatus forms a second layer on a first layer (pattern layer hatched in FIGS. 5A to 5C) formed on the substrate, the second layer being flatter than the first layer, by forming the formable material into a desired shape with the mold having a flat surface. In this specification, the term “first layer” does not mean the layer located first from the base. When, for example, a semiconductor device is manufactured, several tens to several hundreds of layers may be formed. In such a case, the “first layer” may be a layer other than the layer located first from the base.

The formable material ML may be a photo-curable resin. The formable material ML may contain a polymerizable compound and a photopolymerization initiator. The formable material may also contain a non-polymerizable compound or a solvent. The non-polymerizable compound may contain, for example, at least one of a sensitizer, a hydrogen donor, an internal releasing agent, a surface active agent, an antioxidant, and a polymer component.

The formable material ML to be used may depend on the device manufacturing process that is used. In the present embodiment, for example, a material that is more sensitive to light with a wavelength of 300 to 350 nm than to light with other wavelengths is used as the formable material. The sensitivity of the formable material ML to light with a wavelength of 300 to 350 nm may be greater than or equal to 5 times, more preferably 8 times the sensitivity of the formable material ML to light with a wavelength of 350 to 400 nm.

Unlike super high pressure mercury lamps, the LEDs (light emitting elements) of the LED modules have a single wavelength, and the light emission intensity thereof depends on the wavelength. In general, the light emission intensity of LEDs having a wavelength of 300 to 350 nm is greatly lower than that of LEDs having a wavelength of greater than or equal to 365 nm. According to the present embodiment, since the light-emitting-element array 11 is placed on the stage 40, which has less layout restrictions than the head, the illuminance on the formable material illuminated with the curing light can be easily increased. In addition, since the light-emitting-element array 11 is placed on the stage 40, maintenance, such as replacement of the LEDs, can be facilitated.

The forming apparatus may be required to have a structure such that the gap (before contact) between the mold and the substrate to which the formable material is applied is small depending on the positional accuracy in the forming process. Therefore, according to the present embodiment, the light-emitting-element array is disposed in a recess formed in the stage 40 so that the top end of the light-emitting-element array is below the holding surface of the chuck 41.

In the present embodiment, the light-emitting-element array 11 is placed on the stage 40. Therefore, even when the chuck 41 is replaced, the light-emitting-element array 11 can be used continuously. In addition, reduction in the flatness of the holding surface can be prevented when the chuck 41 is processed or manufactured. However, the light-emitting-element array 11 may be placed on the chuck 41 instead of the stage 40 depending on the processing technology or the required accuracy. In such a case, the size of the chuck 41 may be increased in the directions along the holding surface (X and Y directions in this case), and the light-emitting-element array 11 may be disposed outside the holding surface of the chuck 41 (in regions near the edge).

The light-emitting-element array 11 may include a plurality of LEDs having different wavelengths. Even when a user who operates the apparatus changes the formable material or when the formable material varies in quality, the formable material can be efficiently cured by controlling the radiation from the LEDs having different wavelengths.

Some of the LEDs may have wavelengths for which the sensitivity of the formable material is higher than that for the wavelengths of other LEDs that are further away from the chuck 41.

In general, super high pressure mercury lamps are advantageous in that high-intensity ultraviolet rays can be easily obtained, but is disadvantageous in that the radiation system thereof has a large and complex structure. According to the present embodiment, the formable material can be irradiated with a sufficient amount of light by using a simpler structure.

A controller includes a processor, such as a CPU; a storage unit, such as a RAM, a ROM, or an HDD; and an interface unit with which an external device and the processor are interfaced with each other. The interface unit includes a communication interface that provides communication with a host computer. The host computer is, for example, a computer that controls a portion or the entirety of the factory in which the forming apparatus 100 is installed. The processor executes a program stored in the storage unit and controls the operation of the forming processor 101. The controller may include a plurality of circuit boards. A portion or the entirety of the controller may be placed on a rack disposed in a chamber (housing) in which the forming processor is placed, or be placed outside the chamber.

### First Modification

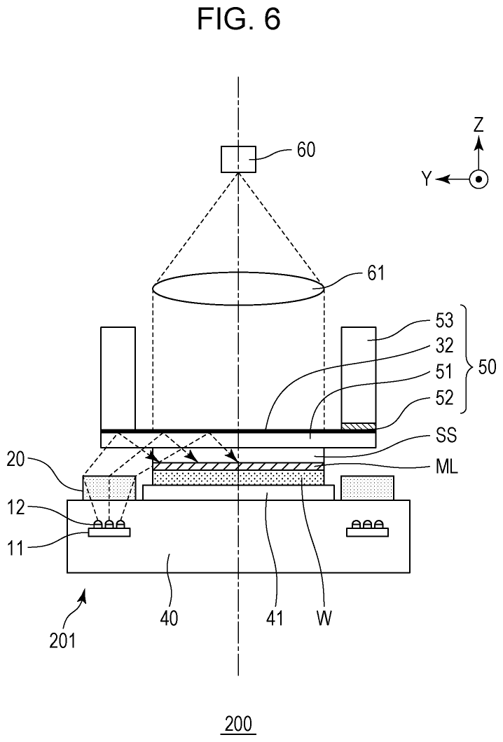

FIG. 6 illustrates a first modification of the optical member 30 illustrated in FIG. 1. Description of components similar to those in FIG. 1 will be omitted.

A forming processor 201 of a forming apparatus 200 includes a reflective film 32 placed on the top surface of the chuck 51 instead of the optical member 30 illustrated in FIG. 1.

As described above with reference to FIGS. 4A to 4C, the reflective film 32 has different reflectances in different regions.

### Second Modification

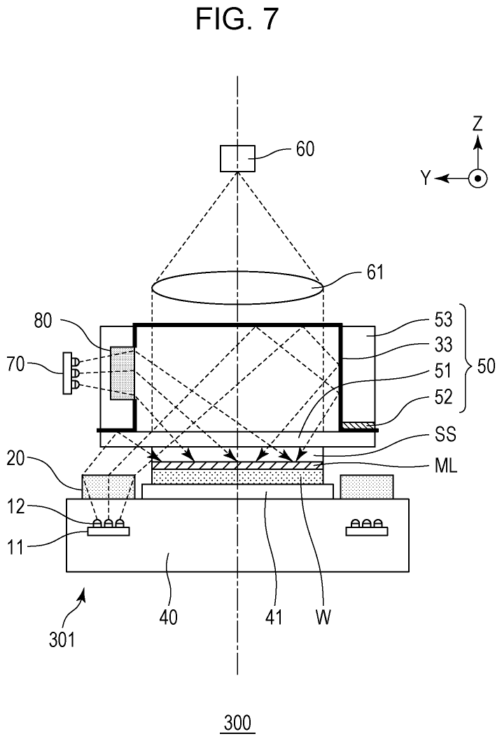

FIG. 7 illustrates a second modification of the optical member 30 illustrated in FIG. 1. Description of components similar to those in FIG. 1 will be omitted.

A forming processor 301 of a forming apparatus 300 includes a reflective film 33 placed on an inner surface of a housing of a head instead of the optical member 30 illustrated in FIG. 1. In this modification, the support unit 53 serves as the housing, and has a tubular shape (not limited to a circular shape and may instead be a polygonal shape).

In addition, in the present embodiment, a light-emitting-element array 70 that is disposed beside the support unit 53 and that functions as the irradiation unit 10 is provided in addition to the light-emitting-element array 11. An optical member 80 is supported on a side surface of the support unit 53, and light from the light-emitting-element array 70 passes through the optical member 80 so that the formable material ML is irradiated with the light. In this modification, the light-emitting-element array 70 is smaller than the light-emitting-element array 11, and is used as an auxiliary light-emitting-element array.

### Third Modification

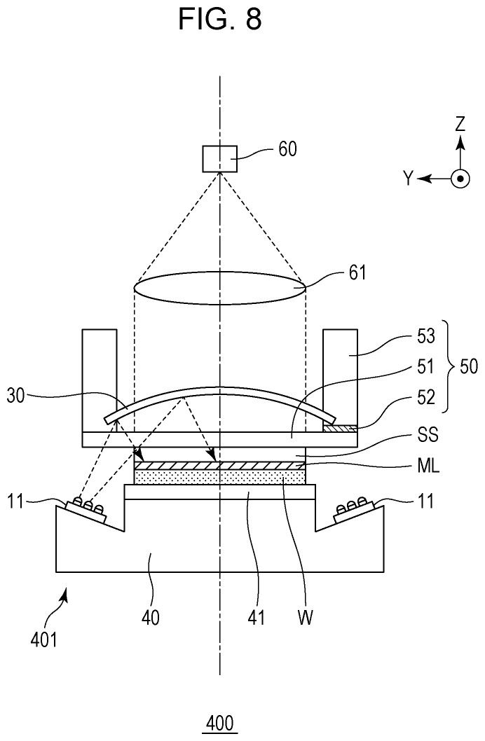

FIG. 8 illustrates a third modification of the irradiation unit illustrated in FIG. 1. Description of components similar to those in FIG. 1 will be omitted.

A forming processor 401 of a forming apparatus 400 is structured such that the light-emitting-element array 11 is inclined relative to the holding surface of the chuck 41 so as to face the center of the chuck 41.

The forming apparatus may be required to have a structure such that the gap (before contact) between the mold and the substrate to which the formable material is applied is small depending on the positional accuracy in the forming process. Therefore, according to the present embodiment, the light-emitting-element array 11 is disposed in a recess formed in the stage 40 so that the top end of the light-emitting-element array 11 is below the holding surface of the chuck 41.

When the light-emitting-element array 11 is inclined as described above, the optical member 20 can be omitted.

The apparatuses described in the above-described embodiment and first to third modifications form the formable material into a desired shape by using a mold having no pattern for a device. Such an apparatus may be referred to as a flattening apparatus. However, the present invention is not limited to a flattening apparatus. For example, the present disclosure may also be applied to an apparatus for forming a formable material into a desired shape by using a mold having a pattern for a device including projections and recesses. Such an apparatus may be referred to as an imprint apparatus or a pattern transfer apparatus, and the “mold” may be referred to as a mask or a template. In addition, the present disclosure may also be applied to a replication apparatus for replicating a mold. In this specification, the term “substrate” includes a blank mold to which a pattern is to be transferred. Such a mold may be referred to as a blank mask or a blank template.

When applied to an imprint apparatus, the forming apparatus according to the above-described embodiment can be particularly advantageously used as an apparatus that simultaneously transfers a pattern to a substrate over the entire surface of the substrate by imprinting. This is because such a simultaneous transfer process requires a larger amount of curing light than when shot (field) regions on the substrate are individually subjected to imprinting. However, the forming apparatus is not limited to an apparatus that performs simultaneous transferring, and may also be advantageously used as, for example, an apparatus that performs transferring on a plurality of shot regions at the same time.

### First Example of Device Manufacturing Method

A method for manufacturing a device (for example, a semiconductor device, a magnetic storage medium, or a liquid crystal display element), which is an article, will now be described. The manufacturing method includes a step of performing a flattening process on a surface of a substrate (for example, a wafer, a glass plate, or a film-shaped substrate) by using the forming apparatus 100.

The manufacturing method further includes a processing step of processing the substrate on which a pattern is formed. The processing step may include a step of forming a device pattern on the layer subjected to the flattening process and a step of removing a residual film of the pattern. The processing step may also include other well-known steps, such as a step of etching the substrate by using the pattern as a mask. The method for manufacturing an article according to the present embodiment is advantageous over methods of the related art in terms of at least one of the performance, quality, ease of production, and production cost of the article.

### Second Example of Device Manufacturing Method

Another method for manufacturing a device (for example, a semiconductor device, a magnetic storage medium, or a liquid crystal display element), which is an article, will now be described. The manufacturing method includes a step of transferring a pattern of a mold onto a surface of a substrate (for example, a wafer, a glass plate, or a film-shaped substrate) by using the forming apparatus 100.

The manufacturing method further includes a processing step of processing the substrate on which a pattern is formed. The processing step may include a step of removing a residual film of the pattern. The processing step may also include other well-known steps, such as a step of etching the substrate by using the pattern as a mask. The method for manufacturing an article according to the present embodiment is advantageous over methods of the related art in terms of at least one of the performance, quality, ease of production, and production cost of the article.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2019-068855 filed Mar. 29, 2019, which is hereby incorporated by reference herein in its entirety.

What is claimed is:

1. A forming apparatus comprising:
a substrate holder that holds a substrate;
a support table that supports the substrate holder;
a mold holder that holds a mold;
a driving unit that brings a formable material and the mold into contact with each other, the formable material being photo-curable and applied to the substrate held by the substrate holder, the mold being held by the mold holder;
an irradiation unit that irradiates the formable material with light for curing the formable material while the formable material and the mold are maintained in contact with each other by the driving unit, the irradiation unit including a light-emitting-element array including a plurality of light emitting elements arranged on the support table or the substrate holder; and
an optical member that is positioned further in a direction from the support table to the mold holder than a position of the mold holder, the optical member guiding light from the plurality of light emitting elements toward the formable material on the substrate.

2. The forming apparatus according to claim 1, wherein the optical member reflects the light from the plurality of light emitting elements and guides the reflected light so that the reflected light passes through the mold and that the formable material is irradiated with the reflected light.

3. The forming apparatus according to claim 1, wherein the light-emitting-element array is disposed on either side of a holding surface of the substrate holder.

4. The forming apparatus according to claim 1, wherein the light-emitting-element array is disposed to extend along an outer periphery of a holding surface of the substrate holder to surround the holding surface.

5. The forming apparatus according to claim 1, wherein the optical member is a concave mirror having a reflective surface that faces the substrate.

6. The forming apparatus according to claim 1, wherein the optical member includes at least two regions, and the two regions have different optical characteristics so that illuminance of light with which the formable material is irradiated is uniform.

7. The forming apparatus according to claim 6, wherein the second optical member includes a diffractive optical element.

8. The forming apparatus according to claim 1, wherein the optical member is a first optical member, and the forming apparatus further comprises a second optical member that is disposed on the support table and that guides light from the light-emitting-element array toward the first optical member.

9. The forming apparatus according to claim 8, wherein the second optical member includes at least two regions, and the two regions have different optical characteristics so that illuminance of light with which the formable material is irradiated is uniform.

10. The forming apparatus according to claim 1, wherein the support table has a recess, and the light-emitting-element array is disposed in the recess so that a top end of the light-emitting-element array is below a holding surface of the substrate holder.

11. The forming apparatus according to claim 1, wherein at least one of the plurality of light emitting elements is an ultraviolet-light emitting device (UV-LED).

12. The forming apparatus according to claim 1, wherein the forming apparatus is configured to simultaneously perform a forming process on an entire surface of the substrate.

13. The forming apparatus according to claim 1, further comprising an observation unit that observes the formable material that is in contact with the mold from above the mold holder.

14. The forming apparatus according to claim 1, wherein the forming apparatus is configured to form the formable material on a first layer on the substrate into a desired shape by using the mold having a flat surface, thereby forming a second layer that is flatter than the first layer on the first layer.

15. A method for manufacturing an article, the method comprising:
forming a layer on a substrate into a desired shape by using a forming apparatus; and
performing etching by using the layer formed into the desired shape or a pattern disposed on the layer formed into the desired shape as a mask,
wherein the forming apparatus comprises:
a substrate holder that holds a substrate;
a support table that supports the substrate holder;
a mold holder that holds a mold;
a driving unit that brings a formable material and the mold into contact with each other, the formable material being photo-curable and applied to the substrate held by the substrate holder, the mold being held by the mold holder;
an irradiation unit that irradiates the formable material with light for curing the formable material while the formable material and the mold are maintained in contact with each other by the driving unit, the irradiation unit including a light-emitting-element array including a plurality of light emitting elements arranged on the support table or the substrate holder; and
an optical member that is positioned further in a direction from the support table to the mold holder than a position of the mold holder, the optical member guiding light from the plurality of light emitting elements toward the formable material on the substrate.
